(19) United States
(12) Patent Application Publication
(10) Pub. No.: US 2009/0323390 A1
(43) Pub. Date: Dec. 31, 2009

(54) SEMICONDUCTOR MEMORY DEVICE

(75) Inventors: Ryousuke Takizawa, Kanagawa-Ken (JP); Shinichiro Shiratake, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/422,083

(22) Filed: Apr. 10, 2009

(30) Foreign Application Priority Data
Jun. 27, 2008 (JP) 2008-168781

(51) Int. Cl. G11C 11/22; G11C 11/24; G11C 8/08; G11C 7/02

(52) U.S. Cl. 365/145; 365/149; 365/230.06; 365/207

(57) ABSTRACT

A memory includes a cell block including ferroelectric capacitors and cell transistors, the cell block being configured by unit cells formed by the ferroelectric capacitor and the cell transistor; a dummy block configured by having one end of dummy strings connected in common, the dummy string being formed by connecting in series dummy transistors; dummy word lines connected to gates of the dummy transistors; a dummy block selection transistor connected between the dummy block and a bit line; wherein in a data read operation, a dummy-word-line driver sets the dummy transistors to a conductive state, the number of the dummy transistors in the conductive state depends on the number of the cell transistors present between the unit cell to be read and the bit line, and the dummy transistors in a conductive state are conductive to the bit line.

### CROSS-REFERENCE TO RELATED APPLICATIONS

This application is based upon and claims the benefit of priority from the prior Japanese Patent Application No. 2008-168781, filed on Jun. 27, 2008, the entire contents of which are incorporated herein by reference.

### BACKGROUND OF THE INVENTION

1. Field of the Invention

The present invention relates to a semiconductor memory device, and for example, relates to a ferroelectric memory that stores logic data based on a polarity of a ferroelectric capacitor.

2. Related Art

A a memory which consists of series connected memory cells each having a transistor having a source terminal and a drain terminal and a ferroelectric capacitor inbetween the two terminals, hereafter named “Series connected TC unit type ferroelectric RAM”, has been developed (D. Takashima et al., “High-density chain Ferroelectric random memory (CFeRAM)” in proc. VLSI Symp. June 1997, pp. 83-84).

In the series connected TC unit type ferroelectric memory (hereinafter, also simply called “ferroelectric memory”), a sense amplifier reads data from a certain unit cell of a cell block including plural unit cells connected in series. At this time, there are cases that an unselected unit cell is present between a unit cell to be read and a bit line. The number of unselected unit cells present is different depending on a position of a unit cell to be read. Capacitance of an unselected unit cell is added to bit line capacitance at a data reading time. Therefore, bit line capacitance varies depending on a position of a unit cell to be read.

When bit line capacitance varies according to a position of a unit cell to be read, an operation point at a data reading time is different according to a position of the unit cell to be read. This becomes a cause of decreasing a sense margin.

### SUMMARY OF THE INVENTION

A semiconductor memory device according to an embodiment of the present invention comprises: a cell block including a plurality of ferroelectric capacitors respectively including a ferroelectric film provided between a first electrode and a second electrode and including a plurality of cell transistors provided corresponding to the ferroelectric capacitors, the cell block being configured by having a plurality of unit cells connected in series, the unit cell being respectively formed by connecting one of the ferroelectric capacitors and one of the cell transistors in parallel; a plurality of word lines connected to gates of the cell transistors; a selection transistor connected to one end of the cell block; a bit line connected to the one end of the cell block via the selection transistor; a plate line connected to the other end of the cell block; a dummy block configured by having one end of a plurality of dummy strings connected in common, the dummy string being respectively formed by connecting in series a plurality of dummy transistors; a plurality of dummy word lines connected to gates of the dummy transistors; a dummy block selection transistor connected between the dummy block and the bit line; a sense amplifier connected to the bit line; a word line driver connected to the word lines; and a dummy-word-line driver connected to the dummy word lines, wherein

in a data read operation, the dummy-word-line driver sets the dummy transistors to a conductive state,

the number of the dummy transistors in the conductive state depends on the number of the cell transistors present between the unit cell to be read and the bit line, and the dummy transistors in a conductive state are conductive to the bit line.

A semiconductor memory device according to an embodiment of the present invention comprises: a cell block including a plurality of ferroelectric capacitors respectively including a ferroelectric film provided between a first electrode and a second electrode and including a plurality of cell transistors provided corresponding to the ferroelectric capacitors, the cell block being configured by having a plurality of unit cells connected in series, the unit cell being respectively formed by connecting one of the ferroelectric capacitors and one of the cell transistors in parallel; a plurality of word lines connected to gates of the cell transistors; a selection transistor connected to one end of the cell block; a bit line connected to the one end of the cell block via the selection transistor; a plate line connected to the other end of the cell block; a dummy block configured by a plurality of dummy strings, each dummy string being formed by connecting in series a plurality of dummy transistors; a plurality of dummy word lines connected to gates of the dummy transistors; a sense amplifier connected to the bit line; a word line driver connected to the word lines; and a dummy-word-line driver connected to the dummy word lines, wherein

a pair of two of the bit lines each transmitting information data and reference data are connected to the sense amplifier,

the sense amplifier detects a logical value of the information data based on the reference data,

the dummy block is connected between the pair of the two bit lines,

in a data read operation, the dummy-word-line driver sets the dummy transistors to a conductive state,

the number of the dummy transistors in the conductive state depends on the number of the cell transistors present between the unit cell to be read and the bit line, and

the dummy transistors in a conductive state are conductive to the bit line.

### BRIEF DESCRIPTION OF THE DRAWINGS

FIG. 1 is a configuration diagram showing one example of a ferroelectric memory according to a first embodiment of the present invention;

FIG. 2 is a circuit diagram showing the cell blocks CB and a reference generating circuit RG according to the first embodiment;

FIG. 3 is a circuit diagram showing the dummy block DB and dummy block selection transistors STdb0 and STdb1 according to the first embodiment;

FIG. 4 is a circuit diagram showing an internal configuration of the dummy block decoder DBD and the DWL driver DWLD;

FIG. 5 is a timing diagram showing one example of a data read operation of the ferroelectric memory according to the first embodiment;

FIG. 6 is a circuit diagram showing the dummy block DB according to a second embodiment of the present invention; and

FIG. 7 is a circuit diagram showing an internal configuration of the DWL driver DWLD according to the second embodiment.

### DETAILED DESCRIPTION OF THE INVENTION

Embodiments of the present invention will be explained below in detail with reference to the accompanying drawings. Note that the invention is not limited thereto.

### First Embodiment

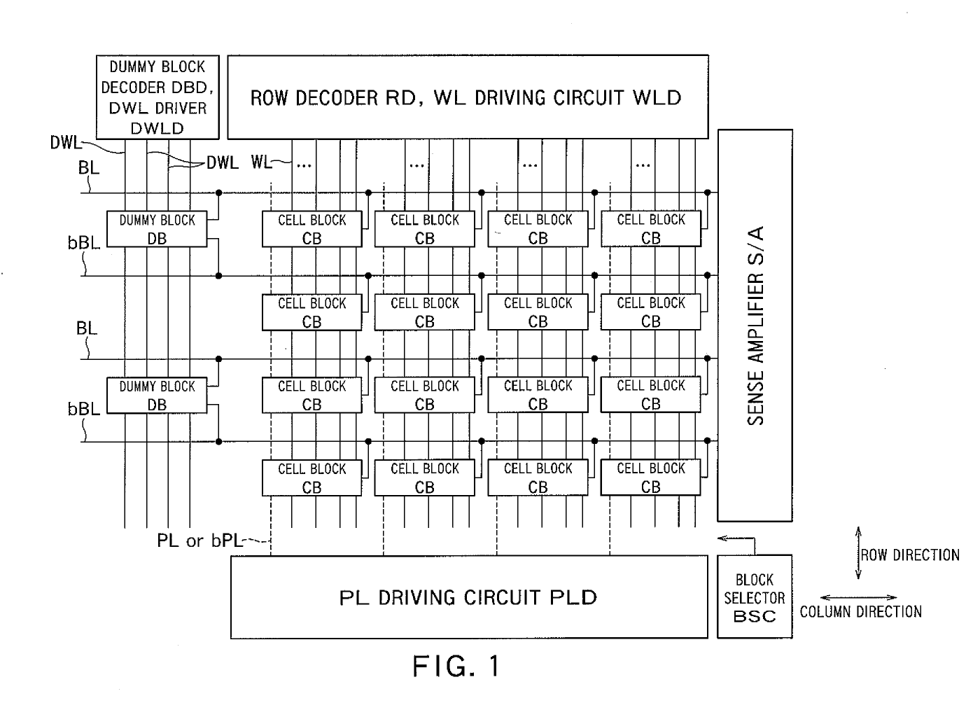

FIG. 1 is a configuration diagram showing one example of a ferroelectric memory according to a first embodiment of the present invention. The ferroelectric memory according to the first embodiment includes plural word lines WL extended to a row direction, plural bit lines BL and bBL extended to a column direction orthogonal with a row direction, and plural plate lines PL and bPL extended to a row direction. In FIG. 1, the plate lines PL and bPL are shown by broken lines to distinguish these plate lines from the word lines WL. Each one bit line BL and each one bit line bBL form a pair, and transmit mutually complementary data. Each plate line PL and each plate line bPL also form a pair, and transmit mutually complementary signals.

Plural cell blocks CB, each including plural unit cells, are arranged in a matrix shape of 4×4. Each cell block CB is connected between one bit line BL and one plate line PL, or between one bit line bBL and one plate line bPL.

A word-line driving circuit WLD is connected to the word lines WL. The word-line driving circuit WLD selects a part (singular or plural) of the word lines WL following an address received from a row decoder RD, and applies a voltage to the selected word line(s) WL. A sense amplifier S/A is connected to the bit lines BL and bBL. At a data reading time, the sense amplifier S/A detects data from a unit cell propagating to a pair of bit lines BL and bBL. At a data writing time, the sense amplifier S/A selects a part (singular or plural) of the bit lines BL and bBL, and applies a voltage to the selected bit line(s) BL and bBL. Accordingly, the sense amplifier S/A can write data via the bit lines BL and bBL connected to the selected word lines. By applying a voltage to the word lines WL and the bit line BL in this way, data can be written into each unit cell positioned at an intersection between the word line WL and the bit line BL, or data can be read from each unit cell. A plate-line driving circuit PLD is configured to apply a voltage to the plate lines PL and bPL at a data reading time or at a data writing time.

FIG. 1 shows the cell blocks CB arranged in a matrix shape of 4×4. However, the number of cell blocks is not limited thereto, and accordingly the numbers of the word lines WL, the bit lines BL and bBL, and the plate lines PL and bPL are also not limited.

The ferroelectric memory according to the first embodiment further includes dummy blocks each connected between each pair of the bit lines BL and bBL, plural dummy word lines DWL extended to a row direction, a dummy block decoder DBD, and a dummy-word-line driver DWLD (hereinafter, “DWL driver DWLD”) that drives the dummy word lines DWL. The DWL driver DWLD selects a part (singular or plural) of the dummy word lines DWL following an address received from the dummy block decoder DBD, and applies a voltage to the selected dummy word line(s) DWL. Each dummy block DB is provided to suppress a variation of bit line capacitance according to a position of a unit cell to be read, at a reading time.

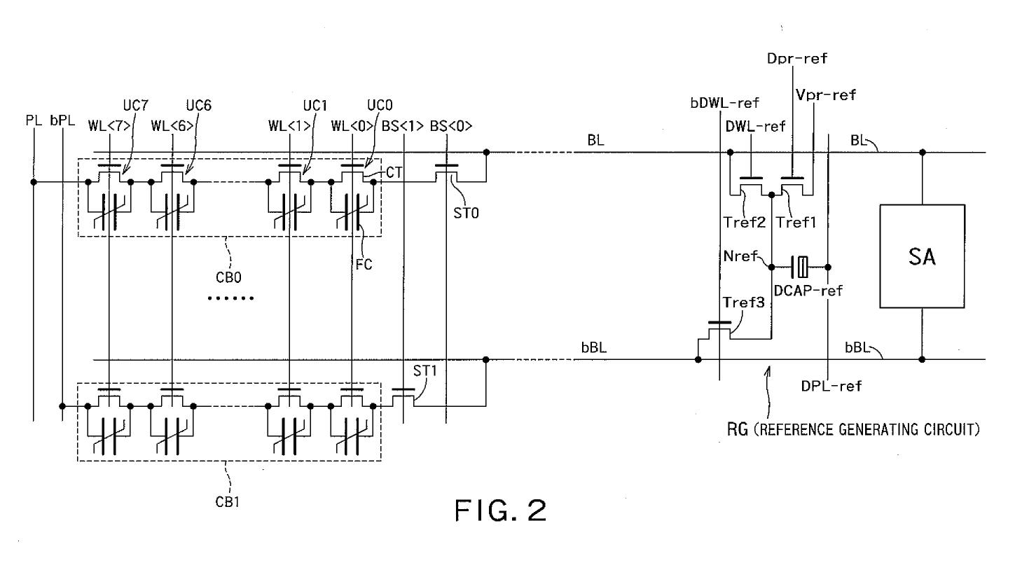

FIG. 2 is a circuit diagram showing the cell blocks CB and a reference generating circuit RG according to the first embodiment. The reference generating circuit RG is omitted from FIG. 1.

Each of cell blocks CB0 and CB1 includes plural ferroelectric capacitors FC each including a ferroelectric film provided between a first electrode and a second electrode, and plural cell transistors CT provided corresponding to the ferroelectric capacitors FC. Each ferroelectric capacitor FC and each corresponding cell transistor CT are connected in parallel with each other, and each set of the ferroelectric capacitor and the corresponding cell transistor constitute a unit cell UC0 to a unit cell UC7. The cell blocks CB0 and CB1 are configured by connecting the unit cells UC0 to UC7 in series. In the first embodiment, the cell blocks CB0 and CB1 are configured by connecting eight unit cells UC0 to UC7 in series. However, the cell blocks can be configured by nine or more unit cells or seven or a smaller number of unit cells. An internal configuration of each of other cell blocks CB shown in FIG. 1 is identical to an internal configuration of the cell block CB0 or CB1. The unit cells UC0 to UC7 are memory cells that store binary data or multi-bit data into the ferroelectric capacitors.

One end of the cell block CB0 is connected to the bit line BL via a selection transistor ST0. The other end of the cell block CB0 is connected to the plate line PL. One end of the cell block CB1 is connected to the bit line bBL via a selection transistor ST1. The other end of the cell block CB1 is connected to the plate line bPL.

Gates of the cell transistors of the unit cells UC0 to UC7 are connected to word lines WL<0> to WL<7>, respectively. Gates of the selection transistors ST0 and ST1 are controlled by block selection signals BS0 and BS1, respectively. The block selection signals BS0 and BS1 are generated by a block selector circuit BSC shown in FIG. 1.

The reference generating circuit RG is provided to generate reference data. The reference generating circuit RG includes a reference node Nref in which reference data is generated, a reference capacitor DCAP-ref that boosts a voltage of the reference node Nref, a precharge voltage Vpr-ref that precharges the reference node Nref, a transistor Tref1 connected between the precharge voltage Vpr-ref and the reference node Nref, a transistor Tref2 connected between the bit line BL and the reference node Nref, and a transistor Tref3 connected between the bit line bBL and the reference node Nref.

One end of the reference capacitor DCAP-ref is connected to the reference node Nref, and the other end of the reference capacitor DCAP-ref is connected to a reference plate line DPL-ref.

The transistor Tref1 is controlled by a signal Dpr-ref, and is in an on-state (conductive state) to charge the reference node Nref to the precharge voltage Vpr-ref before a read operation. In the read operation, the transistor Tref1 becomes in an off-state (nonconductive state).

The transistor Tref2 is controlled by a signal DWL-ref, and becomes in an on-state to transfer reference data to the bit line BL in a read operation. At this time, information data is transmitted from the cell block CB1 to the bit line bBL. The transistor Tref3 is controlled by a signal bDWL-ref, and becomes in an on-state to transfer reference data to the bit line bBL in a read operation. At this time, information data is transmitted from the cell block CB0 to the bit line bBL. That is, when the sense amplifier S/A detects information data transmitted to the bit line bBL, the reference node Nref is connected to the bit line BL, and reference data is transferred to the bit line BL. When the sense amplifier S/A detects information data transmitted to the bit line BL, the reference node Nref is connected to the bit line bBL, and reference data is transferred to the bit line bBL.

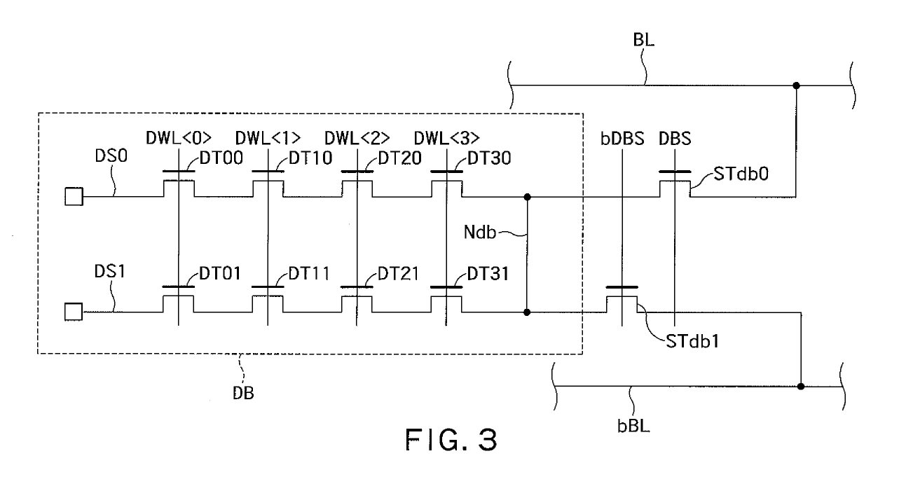

FIG. 3 is a circuit diagram showing the dummy block DB and dummy block selection transistors STdb0 and STdb1 according to the first embodiment. The dummy block selection transistors STdb0 and STdb1 are omitted from FIG. 1.

The dummy block DB includes a dummy string DS0 configured by having plural dummy transistors DT00, DT10, DT20, and DT30 connected in series, and a dummy string DS1 configured by having plural dummy transistors DT01, DT11, DT21, and DT31 connected in series. One end of the dummy strings DS0 and DS1 are connected in common to a node Ndb. The other ends of the dummy strings DS0 and DS1 are in a floating state.

Gates of the dummy transistors DT00, DT10, DT20, and DT30 are connected to dummy word lines DWL<0> to DWL<3>, respectively. Gates of the dummy transistors DT01, DT11, DT21, and DT31 are also connected to dummy word lines DWL<0> to DWL<3>, respectively. That is, gates of dummy transistors DTi0 and DTi1 included in the dummy strings DS0 and DS1 are connected in common to dummy word lines DWL<i>, where i represents any of 0, 1, 2, or 3.

Preferably, sizes (gate width and gate length) of the dummy transistors DT00 to DT31 are substantially equal to sizes (gate width and gate length) of the cell transistors CT. Accordingly, parasitic capacitances of sources and drains of the dummy transistors DT00 to DT31 become equal to parasitic capacitances of sources and drains of the cell transistors CT, respectively. Reasons for setting equal the parasitic capacitances of sources and drains are described later

One end (the node Ndb) of the dummy block DB is connected to the bit line BL via the dummy block selection transistor STdb0, and is also connected to the bit line bBL via the dummy block selection transistor STdb1. The dummy block selection transistor STdb0 is connected between the node Ndb and the bit line BL, and connects the node Ndb to the bit line BL by receiving a control of a dummy block selection signal DBS. The dummy block selection transistor STdb1 is connected between the node Ndb and the bit line bBL, and connects the node Ndb to the bit line bBL by receiving a control of a dummy block selection signal bDBS as an inverted signal of the signal DBS. The dummy block selection signals DBS and bDBS are generated by the block selector circuit BSC shown in FIG. 1, in a similar manner to that applied to the block selection signals BS0 and BS1. For example, when the block selection signal BS0 is activated, the block selector circuit BSC activates the dummy block selection signal DBS. On the other hand, when the block selection signal BS1 is activated, the block selector circuit BSC activates the dummy block selection signal bDBS.

Activation means to turn on or drive an element or a circuit, and inactivation means to turn off or stop an element or a circuit. Therefore, it should be noted that a HIGH (high potential level) signal can be an activation signal, and a LOW (low potential level) signal can be an activation signal. For example, an NMOS transistor is activated by setting a gate to HIGH. On the other hand, a PMOS transistor is activated by setting a gate to LOW.

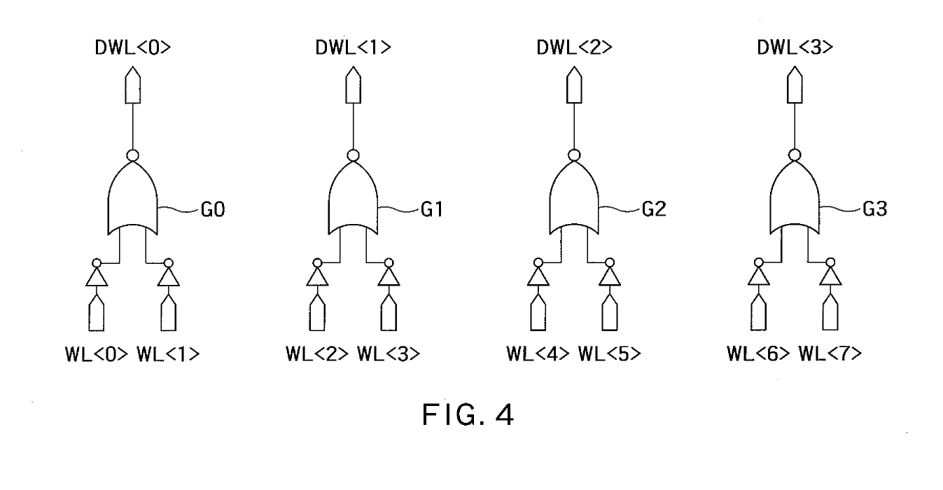

FIG. 4 is a circuit diagram showing an internal configuration of the dummy block decoder DBD and the DWL driver DWLD. The DWL driver DWLD is a logic circuit that generates a driving signal of the dummy word lines DWL<0> to DWL<3> based on a logical value of the driving signals of the word lines WL<0> to WL<7>. In a series connected TC unit type ferroelectric memory, at the time of selecting a memory cell MC, only a potential of a selected word line is set to a logic low, and potentials of other unselected word lines are set to a logic high.

An NOR gate G0 inputs inverted signals of driving signals of the word lines WL<0> and WL<1>, and performs an NOR calculation to these inverted signals. The NOR gate G0 outputs a result of the calculation as a driving signal of the dummy word line DWL<0>. An NOR gate G1 inputs inverted signals of driving signals of the word lines WL<2> and WL<3>, and performs an NOR calculation to these inverted signals. The NOR gate G1 outputs a result of the calculation as a driving signal of the dummy word line DWL<1>. An NOR gate G2 inputs inverted signals of driving signals of the word lines WL<4> and WL<5>, and performs an NOR calculation to these inverted signals. The NOR gate G2 outputs a result of the calculation as a driving signal of the dummy word line DWL<2>. An NOR gate G3 inputs inverted signals of driving signals of the word lines WL<6> and WL<7>, and performs an NOR calculation to these inverted signals. The NOR gate G3 outputs a result of the calculation as a driving signal of the dummy word line DWL<3>.

Accordingly, a dummy word line DWL<m> (m=one of 0 to 3) corresponding to a selected word line WL<j>(j=one of 0 to 7), which is inactivated as the logic low, is inactivated as the logic low. At this time, other dummy word lines DWL<n>(n=0 to 3, n#m) remain as the logic high.

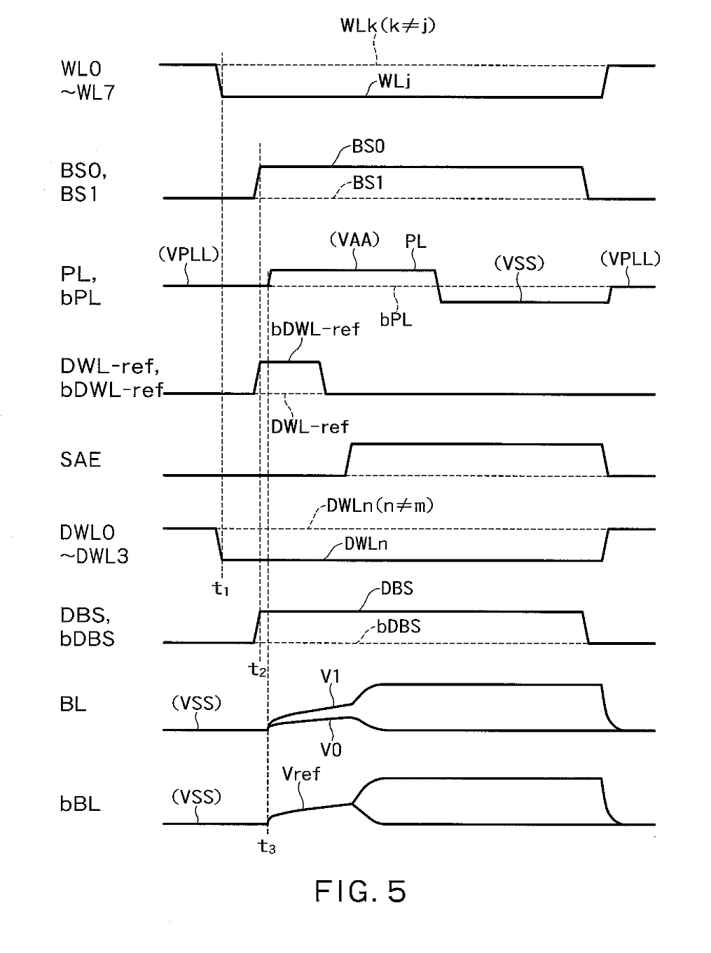

FIG. 5 is a timing diagram showing one example of a data read operation of the ferroelectric memory according to the first embodiment. An operation that the sense amplifier S/A detects information data from the cell block CB0 via the bit line BL is explained here. In this case, reference data is transmitted to the bit line bBL. An operation that the sense amplifier S/A detects information data via the bit line bBL can be easily estimated from the following example, and thus explanations of the operation will be omitted.

In an initial state (up to t1) before a read operation, all word lines WL<0> to WL<7> are in an active state (high level), and the cell transistors CT0 to CT7 are on. All dummy word lines DWL<0> to DWL<3> are in an active state (high level), and the dummy transistors DT00 to DT31 are on. The block selection signals BS0 and BS1 and dummy block selection signals DBS0 and DBS1 are all in an inactive state (low level). Therefore, the cell blocks CB0 and CB1 and the dummy block DB are disconnected from the bit lines BL and bBL.

The plate lines PL and bPL are set to a predetermined potential VPLL. Accordingly, the cell blocks CB0 and CB1 are precharged to the potential VPLL. The predetermined potential VPLL is sometimes equal to VSS or VPL.

The signals DWL-ref and bDWL-ref are in an inactive state. Accordingly, the reference generating circuit RG is also disconnected from the bit lines BL and bBL. Although not shown in FIG. 5, the signal Dpr-ref is in an active state (high level), and the node Nref is precharged to the potential Vpr-ref.

In a precharged state, the bit lines BL and bBL are precharged to a low level potential VSS by the sense amplifier S/A. Each of the unit cells UC0 to UC7 accumulates a precharge based on the plate voltage VPLL in the parasitic capacitance of the cell transistor CT. The precharge of the cell transistor CT also gives an influence to a change of a capacitance of the bit line.

At time t1, the word-line driving circuit WLD shown in FIG. 1 selects a certain word line WL<j>(j=any of 0 to 7), and inactivates the selected word line WL<j>. The word-line driving circuit WLD maintains other word lines WL<k>(k=0 to 7, k≠j) in the inactive state. Accordingly, the cell transistor CT of a unit cell UCj connected to the selected word line WL<j> becomes off. The cell transistors CT of other unit cells UCk remain in the on-state.

At the same time, the DWL driver DWLD shown in FIG. 1 selects one of the dummy word lines DWL<m> (m=any of 0 to 3), and sets the selected dummy word line DWL<m> to an inactive state. The selected dummy word line DWL<m> is selected based on the selected word line WL<j>. Other dummy word lines DWL<n>(n=0 to 3, n≠m) maintain the active state. Accordingly, dummy transistors DTm0 and DTm1 connected to the selected dummy word line DWL<m> become off. Other dummy transistors DTn0 and DTn1 remain in the on-state.

At t2, the block selection signal BS0 is activated, and the block selection signal BS1 remains in the inactive state. Accordingly, the cell block CB0 is connected to the bit line BL via a selection transistor ST. The cell block CB1 maintains a state of being isolated from the bit line bBL.

At the same time, the signal bDWL-ref is activated. Accordingly, the transistor Tref3 shown in FIG. 2 is turned on, and the reference node Nref is connected to the bit line bBL via the transistor Tref3. Because the signal DWL-ref remains in the inactive state, the bit line BL is isolated from the reference node Nref.

At this time, the signal DBS is activated. Accordingly, the dummy block selection transistor STdb0 shown in FIG. 3 is turned on, and the dummy block DB is connected to the bit line BL via the dummy block selection transistor STdb0. Because the signal bDBS is in the inactive state, the dummy block DB is not connected to the bit line bBL.

At t3 immediately after t2, the plate line PL is activated with respect to VAA. Accordingly, a potential of the bit line BL changes based on a polarity state (data “0” or data “1”) of the ferroelectric capacitor FC included in the unit cell UCj within the cell block CB0. At the same time, the signal DPL-ref shown in FIG. 2 is started. A signal line of the signal DPL-ref and the node Nref are capacitance coupled by the reference capacitor DCAP-ref. Therefore, a potential of the node Nref is boosted by increasing the potential of the signal DPL-ref. The potential boosted in the node Nref is transmitted to the bit line bBL as reference data.

The sense amplifier S/A detects a potential difference between the reference data Vref transmitted to the bit line bBL and the information data V1 or V0 transmitted to the bit line BL, as shown in FIG. 5.

Operations of the dummy block DB are explained in more detail. Normally, at the time of reading information data of the unit cell UC0 (j=0), for example, there is no unit cell between the unit cell UC0 and the bit line BL. That is, there is no cell transistor between the unit cell UC0 and the bit line BL. At the time of reading information data of the unit cell UC1 (j=1), the unit cell UC1 is present between the unit cell UC1 and the bit line BL. That is, the number of cell transistor(s) present between the unit cell UC1 and the bit line BL is one. Similarly, at the time of reading information data of the unit cell UC2 (j=2), two cell transistors are present between the unit cell UC2 and the bit line BL. At the time of reading information data of the unit cell UCj, j cell transistors are present between the unit cell UCj and the bit line BL. Therefore, at the time of reading information data of the unit cell UC0 (j=0), capacitance of the cell transistor added to the bit line capacitance is substantially zero. On the other hand, at the time of reading information data of the unit cell UC7 (j=7), capacitance of the cell transistor added to the bit line capacitance is 7×Ct. Ct represents parasitic capacitance of a source and a drain of one cell transistor. This means that bit line capacitance changes depending on a position of the unit cell to be read.

In the first embodiment, the DWL driver DWLD sets dummy transistors to a state of conductive to the bit line BL. The number of the dummy transistors set a conductive state depends on the number of cell transistors present between a unit cell to be read and the bit line BL. At the time of transmitting information data of the unit cell UC0 or UC1 (j=0 or 1), for example, the DWL driver DWLD maintains the dummy word lines DWL<1> to DWL<3> in the active state, and sets the dummy word line DWL<0> to an inactive state. Accordingly, six dummy transistors of DT10 to DT31 are connected to the bit line BL to which information data is transmitted. That is, at the time of reading information data of the unit cell UC0 (j=0), the number of cell transistors connected to the bit line is zero, and the number of dummy transistors connected to the bit line is six. Therefore, total capacitance of the cell transistors and the dummy transistors added to the bit line capacitance is 6×Ct. As described above, parasitic capacitance of the source and the drain of the dummy transistor is Ct which is substantially equal to the parasitic capacitance of the cell transistor. At the time of reading information data of the unit cell UC1 (j=1), the number of cell transistors connected to the bit line is one, and the number of dummy transistors connected to the bit line is six. Therefore, total capacitance of the cell transistors and the dummy transistors added to the bit line capacitance is 7×Ct.

At the time of transmitting information data of the unit cell UC2 or UC3 (j=2 or 3), for example, the DWL driver DWLD maintains the dummy word lines DWL<0>, DWL<2>, and DWL<3> in the active state, and sets the dummy word line DWL<1> to an inactive state. Accordingly, four dummy transistors of DT20 to DT31 are connected to the bit line BL to which information data is transmitted. That is, at the time of reading information data of the unit cell UC2 (j=2), the number of cell transistors connected to the bit line is two, and the number of dummy transistors connected to the bit line is four. Therefore, total capacitance of the cell transistors and the dummy transistors added to the bit line capacitance is 6×Ct. At the time of reading information data of the unit cell UC3 (j=3), the number of cell transistors connected to the bit line is three, and the number of dummy transistors connected to the bit line is four. Therefore, total capacitance of the cell transistors and the dummy transistors added to the bit line capacitance is 7×Ct.

At the time of transmitting information data of the unit cell UC4 or UC5 (j=4 or 5), for example, the DWL driver DWLD maintains the dummy word lines DWL<0>, DWL<1>, and DWL<3> in the active state, and sets the dummy word line DWL<2> to an inactive state. Accordingly, two dummy transistors of DT30 and DT31 are connected to the bit line BL to which information data is transmitted. That is, in the first embodiment, at the time of reading information data of the unit cell UC4 (j=4), the number of cell transistors connected to the bit line is four, and the number of dummy transistors connected to the bit line is two. Therefore, total capacitance of the cell transistors and the dummy transistors added to the bit line capacitance is 6×Ct. At the time of reading information data of the unit cell UC5 (j=5), the number of cell transistors connected to the bit line is five, and the number of dummy transistors connected to the bit line is two. Therefore, total capacitance of the cell transistors and the dummy transistors added to the bit line capacitance is 7×Ct.

For example, at the time of transmitting information data of the unit cell UC6 or UC7 (j=6 or 7), the DWL driver DWLD maintains the dummy word lines DWL<0> to DWL<2> in the active state, and sets the dummy word line DWL<3> to an inactive state. Accordingly, the dummy transistor is not connected to the bit line BL to which information data is transmitted. That is, in the first embodiment, at the time of reading information data of the unit cell UC6 (j=6), the number of cell transistors connected to the bit line is six, and the number of dummy transistors connected to the bit line is zero. Therefore, total capacitance of the cell transistors and the dummy transistors added to the bit line capacitance is 6×Ct. At the time of reading information data of the unit cell UC7 (j=7), the number of cell transistors connected to the bit line is seven, and the number of dummy transistors connected to the bit line is zero. Therefore, total capacitance of the cell transistors and the dummy transistors added to the bit line capacitance is 7×Ct.

As explained above, in the first embodiment, transistor capacitance added to the bit line BL to which information data is transmitted is either 6×Ct or 7×Ct, and can be maintained in a state substantially near a constant value. That is, in the first embodiment, the DWL driver DWLD controls the number of dummy transistors connected to the bit line BL so that the sum of the capacitance of cell transistors present between the unit cell UCj to be read and the bit line BL and the capacitance of dummy transistors which become conductive to the bit line BL is maintained near a constant value.

In the first embodiment, sizes of the dummy transistors DT00 to DT31 are substantially equal to sizes of the cell transistors CT. Therefore, the DWL driver DWLD can control the number of dummy transistors connected to the bit line BL so that the sum of the number of cell transistors CT present between the unit cell UCj to be read and the bit line BL and the number of dummy transistors which become conductive to the bit line BL is maintained near a constant value.

By performing the control as described above, capacitance of the bit line BL can be maintained near a constant value regardless of a position of the unit cell UCj to be read. As a result, a variation of the bit lines BL to which a constant logical value is transmitted becomes small, and an erroneous detection of information data by the sense amplifier S/A can be suppressed. Accordingly, data can be correctly detected.

As shown in FIG. 3, the dummy block DB has plural dummy strings DS0 and DS1 connected in parallel, and the dummy strings DS0 and DS1 share the dummy word lines DWL<0> to DWL<3>. Therefore, when the DWL driver DWLD selects any one of the dummy word lines DWL<0> to DWL<3>, plural dummy transistors are driven. For example, when the dummy word line DWL<0> is selected, the dummy transistors DT00 and DT01 are driven. When the dummy word line DWL<m>(m=0 to 3) is selected, the dummy transistors DTn0 and DTm1 are driven. Because plural dummy transistors are driven when the dummy word line DWL<m> is selected, a process variation of the dummy transistor can be suppressed.

When all dummy transistors are connected in series in one dummy block DB, for example, a single dummy transistor is driven when one dummy word line is selected. In this case, when parasitic capacitance of the dummy transistor is deviated to a large extent from parasitic capacitance of the cell transistor due to a process variation, bit line capacitance at the data reading time cannot be corrected. Therefore, a voltage of information data transmitted to the bit line varies, and the sense amplifier S/A erroneously detects data.

On the other hand, when plural dummy transistors are driven based on the selection of the dummy word line DWL<m> as explained in the first embodiment, even when characteristics (such as size and current driving capacity) of one dummy transistors have a variation, a variation of bit line capacitance at the reading time can be suppressed when characteristics of the other dummy transistor are not varied. As a result, voltage of information data transmitted to the bit line is stabilized, and a risk that the sense amplifier S/A erroneously detects data becomes small.

When plural dummy transistors are driven based on the selection of the dummy word line DWL<m>, bit line capacitance at the reading time does not completely become a constant value, and generates a certain level of deviation as described above. For example, in the first embodiment, capacitance of the dummy transistor added to the bit line capacitance is provided at four stages (0, 2Ct, 4Ct, and 6Ct), by providing four dummy word lines DWL<0> to DWL<3> to eight word lines WL<0> to WL<7>. Therefore, the bit line capacitance at the reading time is not completely a constant value, and generates a certain level of deviation ΔCt (ΔCt=7Ct-6Ct) as described above. However, this deviation ΔCt of the bit line capacitance can be predicted by calculation, and there is no problem when the bit line capacitance due to this deviation ΔCt is sufficiently within a prescribed range. When plural dummy transistors are related to one dummy word line DWL, the bit line capacitance can be stably maintained even when characteristics of a certain dummy transistor vary due to a process variation. Therefore, a mode of relating plural dummy transistors to one dummy word line DWL is preferable to a mode of giving an influence to bit line capacitance without suppressing an unpredictable process balance.

The dummy block DB can be made smaller by dividing a dummy string DS into two and by connecting the divided dummy strings in parallel.

Two dummy strings are included in the dummy block DB according to the first embodiment. However, three or more dummy strings can be included in the dummy block DB. The number of the dummy transistors DT connected to the bit line BL at a reading time can be any one of three stages of 0, 3, and 6. When the unit cell to be read is UC0 or UC1, six dummy transistors DT are connected to the bit line BL at the reading time. When the unit cell to be read is any one of UC2 to UC4, three dummy transistors DT are connected to the bit line BL at the reading time. When the unit cell to be read is any one of UC5 to UC7, zero dummy transistor DT is connected to the bit line BL at the reading time. In this case, total capacitance of cell transistors and dummy transistors added to the bit line capacitance ranges from 5Ct to 7Ct. When the dummy block DB is driven as described above, capacitance of the bit line BL to which the information data is transmitted can be relatively stabilized. In this case, three dummy word lines DWL are sufficient. Further, a circuit scale of the DWL driver DWLD can be made small.

Alternatively, when the number of dummy strings included in the dummy block DB is increased, sizes (gate width and gate length) of each dummy transistor can be made small. For example, when four dummy strings are included in the dummy block DB, a gate width of each dummy transistor is set to a half of the gate width of the cell transistor CT. Accordingly, the dummy block DB including the four dummy strings DS connected in parallel has substantially the same function as that of the dummy block DB shown in FIG. 3. In this case, because four dummy transistors DT are connected to one dummy word line DWL, the bit line capacitance can be maintained more stably even when a process variation occurs.

### Modification of First Embodiment

In the present embodiment, capacitance of the bit line BL to which information data is transmitted is corrected. However, capacitance of the bit line bBL to which reference data is transmitted can be also corrected. In this case, the dummy block DB is connected to the bit line bBL by activating the signal bDBS shown in FIG. 3. The number of the dummy transistors DT activated in the dummy block DB is coincided with or set near the number of the cell transistors CT present between the unit cell UCi to be read and the bit line BL. When the unit cell to be read is UC0, for example, the dummy word lines DWL<0> to DWL<3> maintain the inactive state. In this case, the number of the cell transistors CT added to the bit line BL is zero, and the number of the dummy transistors DT added to the bit line bBL is also zero. When the unit cell to be read is UC1 or UC2, only the dummy word line DWL<0> is activated. In this case, the number of the cell transistors CT added to the bit line BL is one or two, and the number of the dummy transistors DT added to the bit line bBL is two. When the unit cell to be read is UC3 or UC4, the dummy word lines DWL<0> and DWL<1> are activated. In this case, the number of the cell transistors CT added to the bit line BL is three or four, and the number of the dummy transistors DT added to the bit line bBL is four. When the unit cell to be read is UCS or UC6, the dummy word lines DWL<0> and DWL<2> are activated. In this case, the number of the cell transistors CT added to the bit line BL is five or six, and the number of the dummy transistors DT added to the bit line bBL is six. When the unit cell to be read is UC7 or UC7, the dummy word lines DWL<0> and DWL<3> are activated. In this case, the number of the cell transistors CT added to the bit line BL is seven or eight, and the number of the dummy transistors DT added to the bit line bBL is eight. A logic configuration of the DWL driver DWLD can be suitably changed to achieve the above operation.

As described above, the number of the dummy transistors DT activated in the dummy block DB is coincided with or is near the number of the cell transistors CT present between the unit cell UCi to be read and the bit line BL. Accordingly, capacitance of the bit line BL to which information data is transmitted and capacitance of the bit line bBL to which reference data is transmitted substantially coincide with each other or are near to each other. That is, bit line capacitance is maintained substantially constant, regardless of a position of the unit cell to be read. Therefore, in the modification, because an operation point at a data reading time becomes stable, an erroneous detection of information data by the sense amplifier S/A can be suppressed.

### Second Embodiment

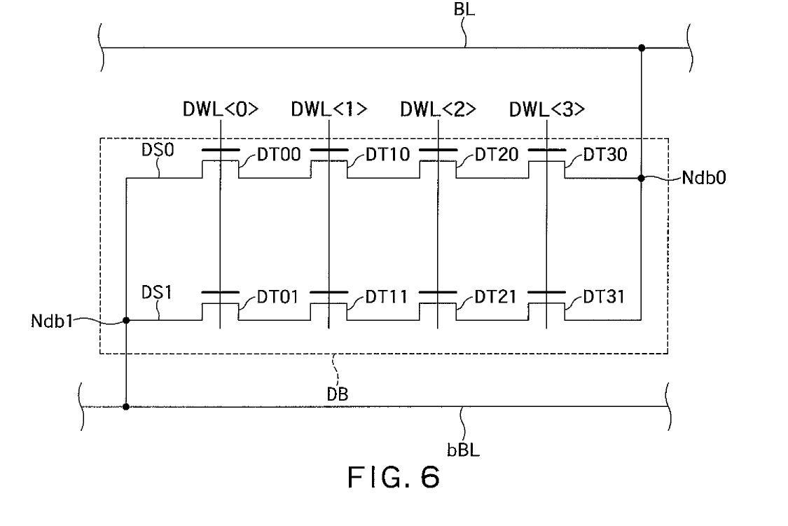

FIG. 6 is a circuit diagram showing the dummy block DB according to a second embodiment of the present invention. Other configurations of the second embodiment can be identical to those of the first embodiment. The dummy block DB according to the second embodiment includes the dummy string DS0 configured by the dummy transistors DT00, DT10, DT20, and DT30, and the dummy string DS1 configured by the dummy transistors DT01, DT11, DT21, and DT31.

The dummy block DB according to the second embodiment is connected between the bit lines BL and bBL. In more detail, a node Ndb0 at one end of the dummy block DB is connected to the bit line BL, and a node Ndb1 at the other end of the dummy block DB is connected to the bit line bBL. Other configurations of the dummy block DB according to the second embodiment can be identical to those of the dummy block DB according to the first embodiment. A connection relationship between the dummy word lines DWL<0> to DWL<3> and the dummy transistors DT00 to DT31 can be also identical to that of the first embodiment.

In the second embodiment, a dummy block selection transistor is not provided. Therefore, at the time of connecting the dummy block DB to the bit lie BL (when the bit line transmits information data), the dummy word line DWL<0> is inactivated, and the dummy block DB is separated from the bit line bBL.

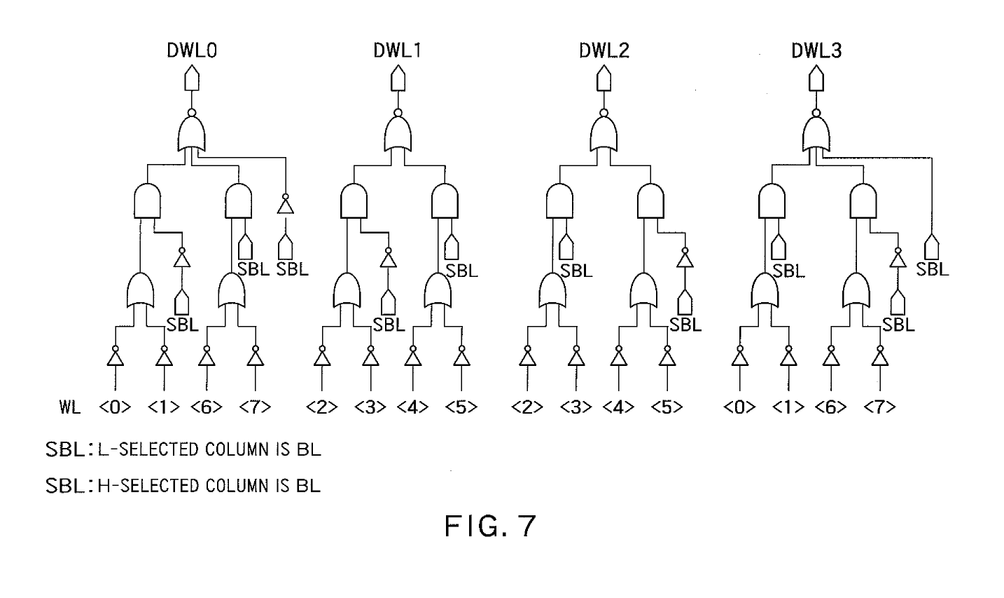

FIG. 7 is a circuit diagram showing an internal configuration of the DWL driver DWLD according to the second embodiment. A signal SBL is a bit-line selection signal, Assume that when the bit line BL is selected and when the bit line bBL is not selected, the signal SBL is at the logic low. Also, assume that when the bit line bBL is selected and when the bit line BL is not selected, the signal SBL is at the logic high. The DWL driver DWLD then operates as follows based on the circuit configuration shown in FIG. 7.

When the selected word line is BL, the dummy word line DWL<0> at the side of the unselected bit line bBL is always in the inactivated state. When the selected word line is bBL, the dummy word line DWL<3> at the side of the unselected bit line BL is always in the inactive state.

[When selected word line is BL (DWL0=LOW)]

When the word line WL<0> or WL<1> is selectively set to the logic low, the DWL driver DWLD sets all the dummy word lines DWL<1> to DWL<3> to the active state. Accordingly, six dummy transistors DT10 to DT31 are connected to the bit line BL.

When the word line WL<2> or <3> is selectively set to the logic low, the DWL driver DWLD sets the dummy word line DWL<1> to the inactive state, and sets the dummy word lines DWL<2> and DWL<3> to the active state. Accordingly, four dummy transistors DT20 to DT31 are connected to the bit line BL.

When the word line WL<4> or <5> is selectively set to the logic low, the DWL driver DWLD sets the dummy word line DWL<2> to the inactive state, and sets the dummy word lines DWL<1> and DWL<3> to the active state. Accordingly, two dummy transistors DT30 and DT31 are connected to the bit line BL.

When the word line WL<6> or <7> is selectively set to the logic low, the DWL driver DWLD sets the dummy word line DWL<3> to the inactive state, and sets the dummy word lines DWL<1> and DWL<2> to the active state. Accordingly, none of the dummy transistors DT10 to DT31 are connected to the bit line BL.

[When selected word line is bBL (DWL3=LOW)]

When the word line WL<0> or WL<1> is selectively set to the logic low, the DWL driver DWLD sets all the dummy word lines DWL<0> to DWL<2> to the active state. Accordingly, six dummy transistors DT00 to DT21 are connected to the bit line BL.

When the word line WL<2> or <3> is selectively set to the logic low, the DWL driver DWLD sets the dummy word line DWL<2> to the inactive state, and sets the dummy word lines DWL<0> and DWL<1> to the active state. Accordingly, four dummy transistors DT00 to DT11 are connected to the bit line BL.

When the word line WL<4> or <5> is selectively set to the logic low, the DWL driver DWLD sets the dummy word line DWL<1> to the inactive state, and sets the dummy word lines DWL<0> and DWL<2> to the active state. Accordingly, two dummy transistors DT00 and DT01 are connected to the bit line BL.

When the word line WL<6> or <7> is selectively set to the logic low, the DWL driver DWLD sets the dummy word line DWL<0> to the inactive state, and sets the dummy word lines DWL<1> and DWL<2> to the active state. Accordingly, none of the dummy transistors DT10 to DT31 are connected to the bit line BL.

Based on the above configurations, the DWL driver DWLD can set the dummy transistors DT to conductive to the bit line BL. The number of the dummy transistors DT in the conductive state depends on the number of cell transistors present between the unit cell UC to be read and the selected bit line BL,.

Referring back to FIG. 5A, a more detailed read operation of a ferroelectric memory according to the second embodiment is explained below. An operation that the sense amplifier S/A detects information data from the cell block CB0 via the bit line BL is explained below. In this case, reference data is transmitted to the bit line bBL. An operation that the sense amplifier S/A detects information data via the bit line bBL can be easily assumed from the following detailed example, and thus explanations thereof will be omitted.

The precharge state in the second embodiment is identical to that in the first embodiment.

At time t1, the DWL driver DWLD inactivates the dummy word line DWL<0>. Accordingly, the dummy transistors DT00 and DT01 are turned of, and the dummy block DB is disconnected from the bit line bBL. During an operation period of reading information data from the bit line BL, the dummy word line DWL<0> maintains the inactive state.

At the same time, the DWL driver DWLD controls the number of dummy transistors becoming conductive to the bit line BL, so that the sum of capacitance of the cell transistors present between the UCj to be read and the bit line BL and capacitance of the dummy transistors DT becoming conductive to the bit line BL is maintained near a constant value.

When the unit cell UC0 or UC1 is the unit cell to be read, the DWL driver DWLD sets the dummy word lines DWL<1> to DWL<3> to the active state. Accordingly, capacitance of the dummy transistors DT added to the bit line BL becomes 6×Ct. At this time, total capacitance of the cell transistors and the dummy transistors added to the bit line capacitance becomes 6×Ct or 7×Ct.

When the unit cell UC2 or UC3 is the unit cell to be read, the DWL driver DWLD maintains the dummy word line DWL<1> in the inactive state, and sets the dummy word lines DWL<2> and DWL<3> to the active state. Accordingly, capacitance of the dummy transistors DT added to the bit line BL becomes 4×Ct. At this time, total capacitance of the cell transistors and the dummy transistors added to the bit line capacitance becomes 6×Ct or 7×Ct.

When the unit cell UC4 or UC5 is the unit cell to be read, the DWL driver DWLD sets the dummy word line DWL<2> to the inactive state, and sets the dummy word lines DWL<1> and DWL<3> to the active state. Accordingly, capacitance of the dummy transistors DT added to the bit line BL becomes 2×Ct. At this time, total capacitance of the cell transistors and the dummy transistors added to the bit line capacitance becomes 6×Ct or 7×Ct.

When the unit cell UC6 or UC7 is the unit cell to be read, the DWL driver DWLD sets the dummy word line DWL<3> to the inactive state, and sets the dummy word lines DWL<1> and DWL<2> to the active state. Accordingly, capacitance of the dummy transistors DT added to the bit line BL becomes zero. At this time, total capacitance of the cell transistors and the dummy transistors added to the bit line capacitance becomes 6×Ct or 7×Ct.

As described above, the sum of the number of the cell transistors CT present between the unit cell UCj to be read and the bit line BL and the number of the dummy transistors DT becoming conductive to the bit line BL is maintained at six or seven. Accordingly, capacitance of the bit line BL at the reading time is maintained near a constant value. Thus, the second embodiment can achieve identical effects to those of the first embodiment.

The number of dummy strings included in the dummy block DB according to the second embodiment can be three or more in a similar manner to that of the first embodiment. In this case, sizes (gate width and gate length) of each dummy transistor can be made small, similarly to the first embodiment. Furthermore, the modification of the first embodiment can be applied to the second embodiment.

1. A semiconductor memory device comprising:
a cell block comprising a plurality of ferroelectric capacitors respectively comprising a ferroelectric film between a first electrode and a second electrode and comprising a plurality of cell transistors corresponding to the ferroelectric capacitors, the cell block comprising a plurality of unit cells connected in series, the unit cell comprising one of the ferroelectric capacitors and one of the cell transistors connected in parallel;
a plurality of word lines connected to gates of the cell transistors;
a selection transistor connected to a first end of the cell block;
a bit line connected to the first end of the cell block via the selection transistor;
a plate line connected to a second end of the cell block;
a dummy block comprising a first end of a plurality of dummy strings connected in common, the dummy string comprising a plurality of dummy transistors connected in series;
a plurality of dummy word lines connected to gates of the dummy transistors;
a dummy block selection transistor connected between the dummy block and the bit line;
a sense amplifier connected to the bit line;
a word line driver connected to the word lines; and
a dummy-word-line driver connected to the dummy word lines, wherein
the dummy-word-line driver is configured to set the dummy transistors to a conductive state in a data read operation,
the number of the dummy transistors in the conductive state corresponds with the number of the cell transistors between the unit cell to be read and the bit line, and
the dummy transistors in a conductive state are conductive to the bit line.

2. The device of claim 1, wherein the dummy-word-line driver is configured to control a number of the dummy transistors conductive to the bit line in order to maintain a sum of capacitance of the cell transistors between the unit cell to be read and the bit line and capacitance of the dummy transistors conductive to the bit line to about a constant value in a data read operation.

3. The device of claim 1, wherein
a gate width and a gate length of the dummy transistors are substantially equal to a gate width and a gate length of the cell transistors, and
the dummy-word-line driver is configured to control a number of the dummy transistors conductive to the bit line in order to maintain a sum of a number of transistors between the unit cell to be read and the bit line and the number of the dummy transistors conductive to the bit line to about a constant value, in a data read operation.

4. The device of claim 2, wherein
a gate width and a gate length of the dummy transistors are substantially equal to a gate width and a gate length of the cell transistors respectively, and
the dummy-word-line driver is configured to control a number of the dummy transistors conductive to the bit line in order to maintain a sum of a number of transistors between the unit cell to be read and the bit line and the number of the dummy transistors conductive to the bit line to about a constant value, in a data read operation.

5. The device of claim 1, wherein
the dummy strings within the same dummy block are configured to share the dummy word lines, and
the dummy-word-line driver is configured to select one of the dummy word lines in order to drive dummy transistors within the dummy block.

6. The device of claim 2, wherein
the dummy strings within the same dummy block are configured to share the dummy word lines, and
the dummy-word-line driver is configured to select one of the dummy word lines in order to drive dummy transistors within the dummy block.

7. The device of claim 3, wherein
the dummy strings within the same dummy block are configured to share the dummy word lines, and
the dummy-word-line driver is configured to select one of the dummy word lines in order to drive dummy transistors within the dummy block.

8. The device of claim 1, wherein
a pair of the bit lines, a first line configured to transmit information data and a second line configured to transmit reference data, are connected to the sense amplifier,
the sense amplifier configured to detect a logical value of the information data based on the reference data,
a dummy block corresponding to the pair of the two bit lines is connected to each of the pair of the two bit lines via two of the dummy block selection transistors, and
the dummy block is connected to the first line of the pair of the bit lines when the sense amplifier obtains the information data from the first line of the pair and obtains the reference data from the second line of the pair.

9. The device of claim 2, wherein
a pair of two of the bit lines, a first line configured to transmit information data and a second line configured to transmit reference data, are connected to the sense amplifier,
the sense amplifier is configured to detect a logical value of the information data based on the reference data,
a dummy block corresponding to the pair of the two bit lines is connected to each of the pair of the two bit lines via two of the dummy block selection transistors, and
the dummy block is connected to the first line of the bit lines when the sense amplifier obtains the information data from the first line of the pair and obtains the reference data from the second line of the pair.

10. The device of claim 3, wherein
a pair of two of the bit lines, a first line c onfigured to transmit information data and a second line configured to transmit reference data, are connected to the sense amplifier,
the sense amplifier is configured to detect a logical value of the information data based on the reference data,
a dummy block corresponding to the pair of the two bit lines is connected to each of the pair of the two bit lines via two of the dummy block selection transistors, and
the dummy block is connected to a first bit line of the pair when the sense amplifier receives the information data from a first bit line of the pair and receives the reference data from a second bit line of the pair.

11. The device of claim 5, wherein
a pair of two of the bit lines each transmitting information data and reference data are connected to the sense amplifier,
the sense amplifier is configured to detect a logical value of the information data based on the reference data,
a dummy block corresponding to the pair of the two bit lines is connected to each of the pair of the two bit lines via two of the dummy block selection transistors, and
the dummy block is connected to a first the bit line when the sense amplifier receives the information data from the first bit line of the pair and receives the reference data from a second bit line of the pair.

12. A semiconductor memory device comprising:
a cell block comprising a plurality of ferroelectric capacitors respectively comprising a ferroelectric film between a first electrode and a second electrode and comprising a plurality of cell transistors corresponding to the ferroelectric capacitors, the cell block comprising a plurality of unit cells connected in series, the unit cell comprising one of the ferroelectric capacitors and one of the cell transistors connected in parallel;
a plurality of word lines connected to gates of the cell transistors;
a selection transistor connected to a first end of the cell block;
a bit line connected to the first end of the cell block via the selection transistor;
a plate line connected to a second end of the cell block;
a dummy block comprising a plurality of dummy strings, each dummy string comprising a plurality of dummy transistors connected in series;
a plurality of dummy word lines connected to gates of the dummy transistors;
a sense amplifier connected to the bit line;
a word line driver connected to the word lines; and
a dummy-word-line driver connected to the dummy word lines, wherein
a pair of two of the bit lines each transmitting information data and reference data are connected to the sense amplifier,
the sense amplifier configured to detect a logical value of the information data based on the reference data,
the dummy block is connected between the pair of the two bit lines,
the dummy-word-line driver is configured to set the dummy transistors to a conductive state in a data read operation,
the number of the dummy transistors in the conductive state corresponds with the number of the cell transistors between the unit cell to be read and the bit line, and
the dummy transistors in a conductive state are conductive to the bit line.

13. The device of claim 12, wherein the dummy-word-line driver is configured to control a number of the dummy transistors conductive to the bit line in order to maintain a sum of capacitance of the cell transistors between the unit cell to be read and the bit line and capacitance of the dummy transistors conductive to the bit line to about a constant value in a data read operation.

14. The device of claim 12, wherein
a gate width and a gate length of the dummy transistors are substantially equal to a gate width and a gate length of the cell transistors respectively, and
the dummy-word-line driver is configured to control a number of the dummy transistors conductive to the bit line in order to maintain a sum of a number of transistors between the unit cell to be read and the bit line and the number of the dummy transistors conductive to the bit line about a constant value, in a data read operation.
